(19) United States
(12) Patent Application Publication
(10) Pub. No.: US 2016/0359119 A1
(43) Pub. Date: Dec. 8, 2016

(54) PEROVSKITE SOLAR CELL

(71) Applicant: Panasonic Corporation, Osaka (JP)

(72) Inventors: NAOKI HAYASHI, Kyoto (JP); MICHIO SUZUKA, Osaka (JP)

(21) Appl. No.: 15/163,675

(22) Filed: May 25, 2016

(30) Foreign Application Priority Data
Jun. 4, 2015 (JP) 2015-114004

(51) Int. Cl. H01L 51/00; H01L 51/44; H01L 51/42

(52) U.S. Cl. CPC H01L 51/0077; H01L 51/4213; H01L 51/441; H01L 51/447; H01L 51/0083

(57) ABSTRACT

A perovskite solar cell includes a first electrode; an electron transport layer on the first electrode, containing a semiconductor; a light-absorbing layer on the electron transport layer, containing a perovskite compound represented by a compositional formula ABX₃ where A represents a monovalent cation, B represents a divalent cation, and X represents a halogen anion; a hole transport layer on the light-absorbing layer, containing a hole transport material including a redox moiety, and a second electrode on the hole transport layer. The hole transport layer satisfies 0.1≦100C/(C+D)≦1.1, where C represents a number of moles of the redox moiety in an oxidized state in the hole transport layer, and D represents a number of moles of the redox moiety in a reduced state in the hole transport layer.

### BACKGROUND

1. Technical Field

The present disclosure relates to a perovskite solar cell.

2. Description of the Related Art

In recent years, researches on the development of perovskite solar cells have been underway, the perovskite solar cells using, as a light-absorbing material, a perovskite crystal represented by a compositional formula ABX₃ (A represents a monovalent cation, B represents a divalent cation, and X represents a halogen anion) or a perovskite-like structure. Julian Burschka and six others, “Nature” (US), vol. 499, p. 316-320, July 2013 discloses a perovskite solar cell employing a CH₃NH₃PbI₃ perovskite layer as the light-absorbing layer and employing Spiro-OMeTAD (2,2′,7,7′-tetrakis(N,N-di-p-methoxyphenylamino)-9,9′-spirobifluorene) as the hole transport material. Specifically, the hole transport layer of this solar cell is formed of Spiro-OMeTAD serving as the hole transport material. This layer is doped with a cobalt complex such that the cobalt complex content is 10 mol % to thereby cause partial oxidation of Spiro-OMeTAD. In this way, the conductivity of the hole transport layer is enhanced to thereby increase the conversion efficiency.

### SUMMARY

There has been a demand for a perovskite solar cell having higher durability.

In one general aspect, the techniques disclosed here feature a perovskite solar cell including a first electrode; an electron transport layer on the first electrode, containing a semiconductor; a light-absorbing layer on the electron transport layer, containing a perovskite compound represented by a compositional formula ABX₃ where A represents a monovalent cation, B represents a divalent cation, and X represents a halogen anion; a hole transport layer on the light-absorbing layer, containing a hole transport material including a redox moiety, and a second electrode on the hole transport layer. The hole transport layer satisfies 0.1≦100C/(C+D)≦1.1, where C represents a number of moles of the redox moiety in an oxidized state in the hole transport layer, and D represents a number of moles of the redox moiety in a reduced state in the hole transport layer.

It should be noted that general or specific embodiments may be implemented as an element, a device, a system, an integrated circuit, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view of a perovskite solar cell according to a first embodiment;

FIG. 2 is a sectional view of a perovskite solar cell according to a second embodiment; and

FIG. 3 illustrates the ultraviolet-visible absorption spectra (before heating test and after heating test) of the hole transport layer of a perovskite solar cell of Example 2.

### DETAILED DESCRIPTION

Prior to descriptions of embodiments of the present disclosure, the findings having been found by the inventors will be described.

For the perovskite solar cell disclosed in Julian Burschka and six others, “Nature” (US), vol. 499, p. 316-320, July 2013, the hole transport layer is formed so as to have a high cobalt complex content of 10 mol %, to thereby generate the oxidant moiety in the hole transport material. Thus, a solar cell having high conversion efficiency is provided. However, as time elapses, the oxidant moiety returns to the reductant moiety. As a result, the conversion efficiency of the perovskite solar cell considerably decreases with time.

In contrast, according to an aspect of the present disclosure, the content ratio of the oxidant moiety of the hole transport material in the hole transport layer is appropriately controlled. This can provide a perovskite solar cell having high conversion efficiency and high durability.

Hereinafter, embodiments of the present disclosure will be described with reference to drawings.

### First Embodiment

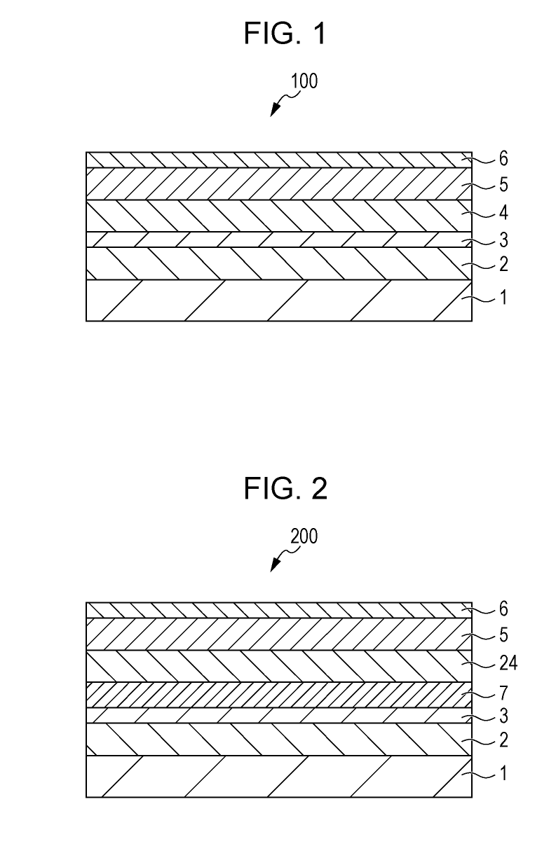

Referring to FIG. 1, a perovskite solar cell 100 according to a first embodiment has a configuration in which, on a substrate 1, a first current-collector electrode 2, an electron transport layer 3, a light-absorbing layer 4, a hole transport layer 5, and a second current-collector electrode 6 are stacked in this order. The electron transport layer 3 contains a semiconductor. The light-absorbing layer 4 contains a perovskite compound represented by a compositional formula ABX₃ where A represents a monovalent cation, B represents a divalent cation, and X represents a halogen anion. The hole transport layer 5 contains a hole transport material. The hole transport material is present in the oxidant or the reductant form. In other word, the hole transport layer 5 contains a hole transport material. The hole transport material includes a redox moiety. The redox moiety turns to an oxidant moiety (also referred to as the redox moiety in oxidized state) by oxidation, and turns to a reductant moiety (also referred to as the redox moiety in reduced state) by reduction. When the number of moles (represented by symbol C) of the oxidant moiety in the hole transport layer and the number of moles (represented by symbol D) of the reductant moiety in the hole transport layer satisfies the following Formula (1).

0.1≦100C/(C+D)≦1.1 (1)

Note that the substrate 1 may be omitted from the perovskite solar cell 100.

The basic operation and effect of the perovskite solar cell 100 of the embodiment are as follows.

Upon entry of light into the perovskite solar cell 100, the light-absorbing layer 4 absorbs the light to generate excited electrons and holes. These excited electrons move to the electron transport layer 3. On the other hand, the holes generated in the light-absorbing layer 4 move to the hole transport layer 5. The electron transport layer 3 is connected to the first current-collector electrode 2. The hole transport layer 5 is connected to the second current-collector electrode 6. Thus, the perovskite solar cell 100 produces current between the first current-collector electrode 2 as the negative electrode and the second current-collector electrode 6 as the positive electrode.

The composition ratio of the hole transport layer 5 satisfies the Formula (1), so that, in the hole transport layer 5, the number of moles of the oxidant of the hole transport material is much smaller than the number of moles of the reductant of the hole transport material. As a result, a decrease in the conversion efficiency of the perovskite solar cell is suppressed even after use for long time. Thus, a perovskite solar cell having high durability can be provided.

The perovskite solar cell 100 according to the embodiment can be produced by, for example, the following method.

The first current-collector electrode 2 is formed on a surface of the substrate 1 by Chemical Vapor Deposition (CVD) or sputtering, for example. On the first current-collector electrode 2, the electron transport layer 3, the light-absorbing layer 4, the hole transport layer 5, and the second current-collector electrode 6 are formed in this order by coating, for example.

Hereinafter, components of the perovskite solar cell 100 will be specifically described.

### Substrate 1

The substrate 1 is an optional component. The substrate 1 physically supports layers of the perovskite solar cell 100.

The substrate 1 may transmit light. For example, the substrate 1 may be selected from glass substrates and plastic substrates (including plastic films). When the second current-collector electrode 6 transmits light, the substrate 1 may be formed so as not to transmit light. In other words, the substrate 1 may be formed of an opaque material. Examples of the material include metals, ceramics, and resin materials.

When the first current-collector electrode 2 has sufficiently high strength, for example, the layers can be supported by the first current-collector electrode 2 and hence the substrate 1 may be omitted.

### First Current-Collector Electrode 2 and Second Current-Collector Electrode 6

The first current-collector electrode 2 and the second current-collector electrode 6 have conductivity. At least one of the first current-collector electrode 2 and the second current-collector electrode 6 transmits light, for example, light ranging from the visible-light region to the near-infrared region. Hereafter, “the first current-collector electrode 2 and the second current-collector electrode 6” is sometimes collectively referred to as a “current-collector electrode”.

The current-collector electrode that transmits light can be formed of a transparent and conductive metal oxide, for example. Examples of the metal oxide include indium-tin compound oxide, antimony-doped tin oxide, fluorine-doped tin oxide, zinc oxide doped with boron, aluminum, gallium, or indium, and composite materials of the foregoing.

The current-collector electrode that transmits light may be formed so as to have a pattern having openings. Examples of the pattern include line patterns (striped patterns), wavy-line patterns, grid patterns (mesh patterns), punching-metal patterns (in which a large number of fine through-holes are arranged regularly or randomly), and inverse patterns of the foregoing patterns. The current-collector electrode that is formed so as to have such a pattern allows light to pass through openings. Examples of the material for the current-collector electrode include platinum, gold, silver, copper, aluminum, rhodium, indium, titanium, iron, nickel, tin, zinc, and alloys containing at least one of the foregoing. Alternatively, the current-collector electrode may be formed of a conductive carbon material.

The current-collector electrode that transmits light may have a transmittance of, for example, 50% or more, or 80% or more. The wavelength of light that the current-collector electrode transmits is selected depending on the wavelength of light that the light-absorbing layer 4 absorbs. The current-collector electrode may have a thickness of 1 nm to 1000 nm, for example.

When one of the first current-collector electrode 2 and the second current-collector electrode 6 transmits light, the other electrode may be formed so as not to transmit light. In this case, the current-collector electrode that does not transmit light may be formed of an opaque electrode material so as not to have the pattern having openings.

### Electron Transport Layer 3

The electron transport layer 3 contains a semiconductor. In particular, the semiconductor preferably has a band gap of 3.0 eV or more. When the electron transport layer 3 is formed of a semiconductor having a band gap of 3.0 eV or more, visible light and infrared light are transmitted to the light-absorbing layer 4. Examples of the semiconductor include organic n-type semiconductors and inorganic n-type semiconductors.

Examples of the organic n-type semiconductors include imide compounds, quinone compounds, fullerene, and derivatives thereof. Examples of the inorganic n-type semiconductors include oxides of metal elements and perovskite oxides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, and Cr. More specifically, an example is TiO₂. Examples of the perovskite oxides include SrTiO₃ and CaTiO₃.

Alternatively, the electron transport layer 3 may be formed of a material having a band gap of more than 6 eV. Examples of the material having a band gap of more than 6 eV include alkali-metal halides such as lithium fluoride, alkaline-earth-metal halides such as calcium fluoride, alkaline-earth-metal oxides such as magnesium oxide, and silicon dioxide. In such cases, in order for the electron transport layer 3 to transport electrons, the electron transport layer 3 may have a thickness of 10 nm or less. The electron transport layer 3 may include plural layers that differ in their materials.

### Light-Absorbing Layer 4

The light-absorbing layer 4 contains a compound having a perovskite structure represented by a compositional formula ABX₃ as the light-absorbing material. In the formula, A represents a monovalent cation. Examples of the cation A include monovalent cations such as alkali-metal cations and organic cations. Specifically, the examples include a methylammonium cation (CH₃NH₃⁺), a formamidinium cation (NH₂CHNH₂⁺), and a cesium cation (Cs⁺). In the formula, B represents a divalent cation. Examples of the cation B include divalent cations of transition metal elements and groups 13 to 15 elements. Specifically, the examples include Pb²⁺, Ge²⁺, and Sn²⁺. In the formula, X represents a monovalent anion such as a halogen anion. Each of the cation A site, the cation B site, and the anion X site may be occupied by plural ion species. Examples of the compound having a perovskite structure include CH₃NH₃PbI₃, NH₂CHNH₂PbI₃, CH₃CH₂NH₃PbI₃, CH₃NH₃PbBr₃, CH₃NH₃PbCl₃, CsPbI₃, and CsPbBr₃.

The thickness of the light-absorbing layer 4 may be selected depending on its degree of light absorption and may be 100 nm to 1000 nm, for example. The light-absorbing layer 4 may be formed by coating with a solution or co-evaporation, for example.

The light-absorbing layer 4 may partially mix with, at its boundaries, the electron transport layer 3 or the hole transport layer 5.

### Hole Transport Layer 5

The hole transport layer 5 contains a hole transport material. The hole transport material includes the oxidant moiety or the reductant moiety. The hole transport material is, for example, an aromatic amine derivative. The aromatic amine derivative is represented by, for example, Chemical Formula 1 below.

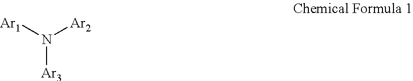

In the Chemical Formula 1, Ar₁, Ar₂, and Ar₃ each independently represent a substituted or unsubstituted aryl group, heteroaryl group, or heterocyclic group. In other word, Ar₁, Ar₂, and Ar₃ each independently represent one selected from a substituted aryl group, unsubstituted aryl group, a substituted heteroaryl group, a unsubstituted heteroaryl group, a substituted heterocyclic group, and a substituted heterocyclic group. Ar₁, Ar₂, and Ar₃ may be linked together to form a ring structure. The hole transport material is not particularly limited in terms of molecular weight and may have a high molecular weight. Such aromatic amine derivatives have a structure in which π conjugated systems spatially spread. Thus, such molecules stacked have a large overlap between π electron clouds, so that movements of electrons between molecules easily occur. For this reason, when such an aromatic amine derivative is used to form the hole transport layer, the resultant layer has a high capability of transporting holes.

Specific examples of aromatic amine derivatives represented by the Chemical Formula 1 include triaryl amine compounds, which each have a triaryl amine structure in the molecule. Some examples of the triaryl amine compounds are represented by Chemical Formulae (1) to (8) below where Ar₄ to Ar₄₀ each independently represent a substituted or unsubstituted aryl group or heterocyclic group; some of Ar₄ to Ar₄₀ may be linked together to form ring structures; n1 and n2 each represent a natural number of 1 to 6, and n3 represents a natural number of 30 to 100.

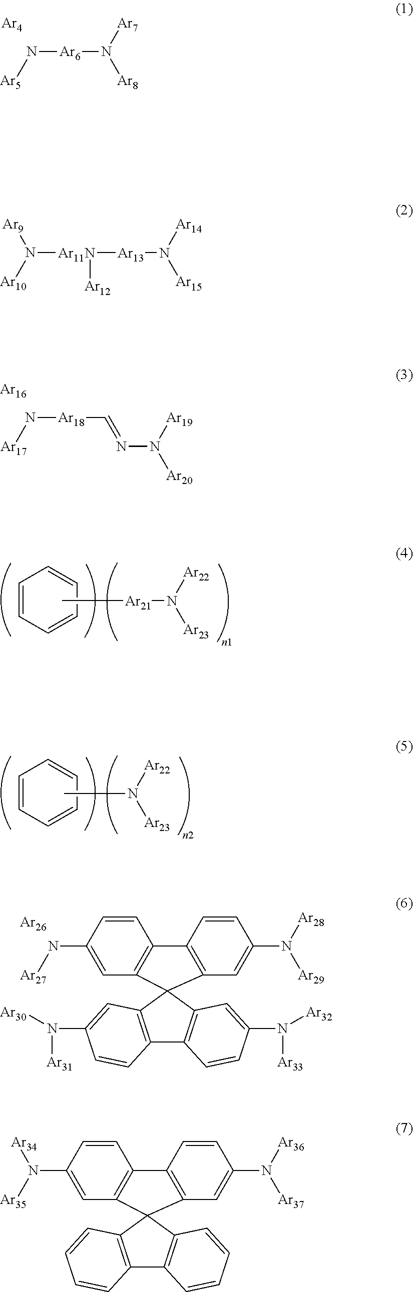

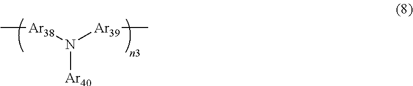

More specific examples of the triaryl amine compounds are represented by Chemical Formulae (9) to (15) below.

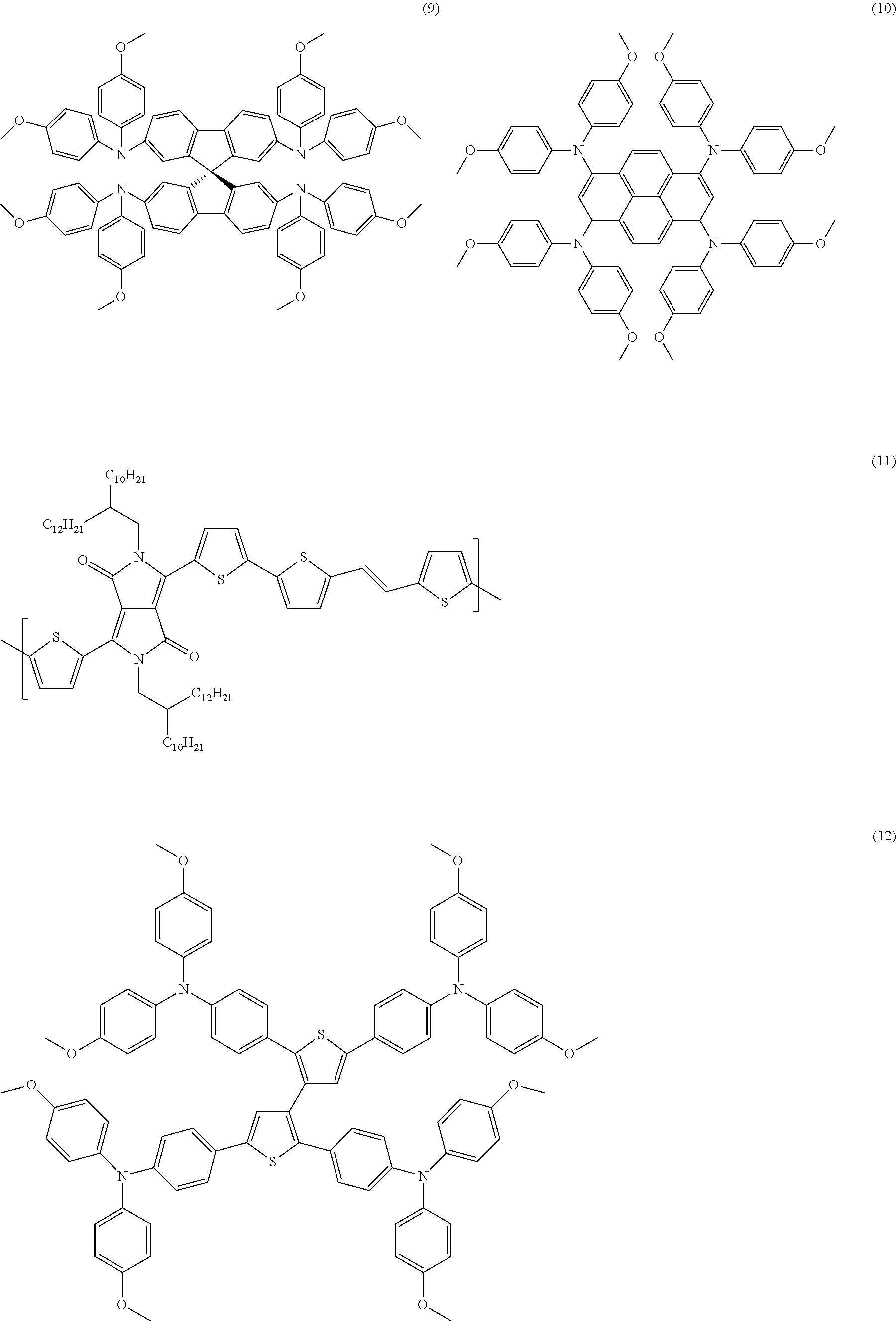

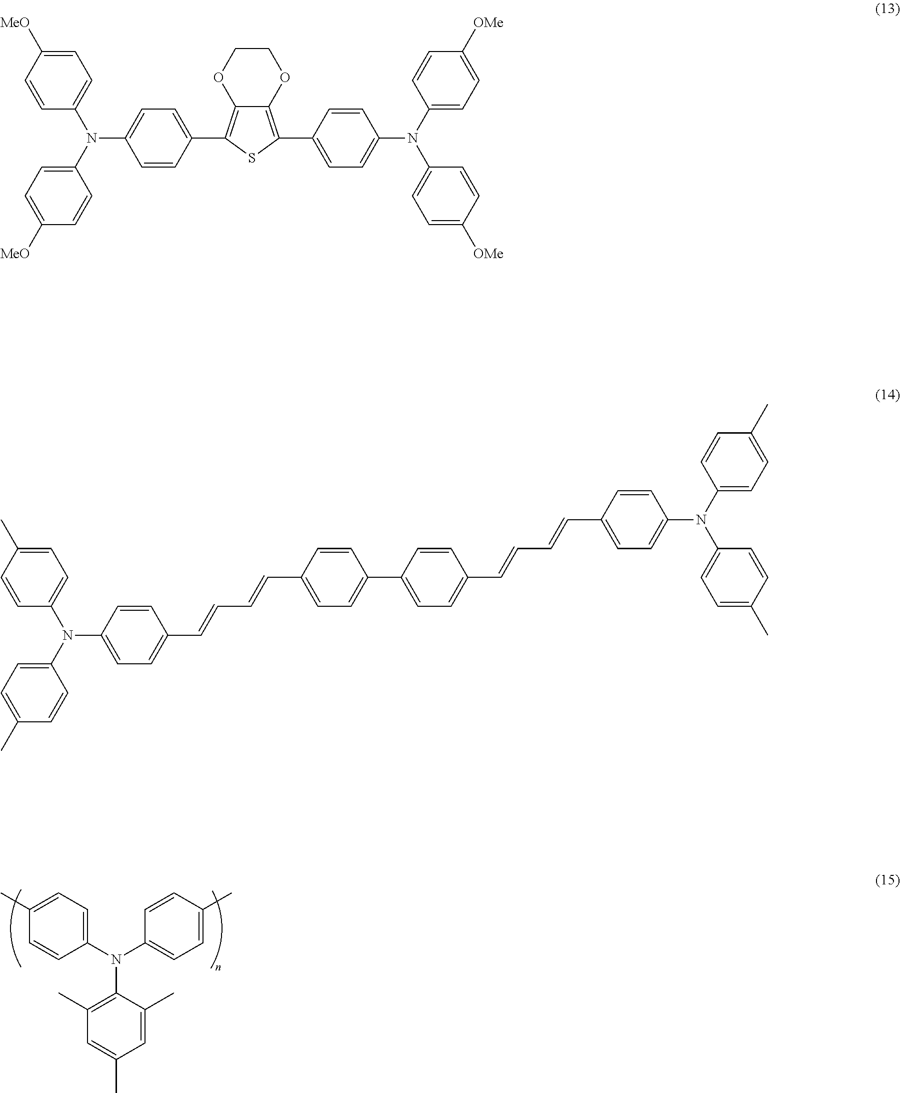

The oxidant moiety of the hole transport material can be formed by subjecting an oxidizing treatment to the hole transport material. The oxidizing treatment is, for example, to bring an oxidizing agent into contact with the reductant of the hole transport material by mixing. The oxidizing agent used for the oxidizing treatment is selected so as to have an oxidation-reduction potential more noble than the HOMO level of the transport material in a reduced state. For example, when the reductant of the hole transport material is Spiro-OMeTAD, an oxidizing agent is selected so as to have an oxidation-reduction potential more noble than the HOMO level of Spiro-OMeTAD, −5.0 eV. When the reductant of the hole transport material is Spiro-OMeTAD, examples of the oxidizing agent include oxygen and cobalt complexes.

The hole transport layer 5 is desirably formed so as to have a thickness of 1 nm or more and 1000 nm or less, more desirably 100 nm or more and 500 nm or less. When the hole transport layer 5 has a thickness in such a range, holes are sufficiently transported. In addition, a low resistance is maintained, so that power generation is carried out at high efficiency.

The hole transport layer 5 may be formed by a coating process or a printing process. Examples of the coating process include doctor-blade coating, bar coating, spray coating, dip coating, and spin coating. An example of the printing process is screen printing. The hole transport layer 5 may be formed from a mixture and pressed or fired, for example. When the hole transport material is a low-molecular-weight organic material or an inorganic semiconductor, the hole transport layer 5 may be formed by vacuum deposition, for example.

The hole transport layer 5 may contain a supporting electrolyte and a solvent.

Examples of the supporting electrolyte include ammonium salts and alkali-metal salts. Examples of the ammonium salts include tetrabutylammonium perchlorate, tetraethylammonium hexafluorophosphate, imidazolium salts, and pyridinium salts. Examples of the alkali-metal salts include lithium perchlorate and potassium tetrafluoroborate.

The solvent contained in the hole transport layer 5 desirably has high ion conductivity. The solvent, which may be selected from aqueous solvents and organic solvents, is desirably selected from organic solvents in order to achieve higher stabilization of the solute. Examples of the organic solvents include carbonate compounds, ester compounds, ether compounds, heterocyclic compounds, nitrile compounds, and aprotic polar compounds. Examples of the carbonate compounds include dimethyl carbonate, diethyl carbonate, methyl ethyl carbonate, ethylene carbonate, and propylene carbonate. Examples of the ester compounds include methyl acetate, methyl propionate, and y-butyrolactone. Examples of the ether compounds include diethyl ether, 1,2-dimethoxyethane, 1,3-dioxolane, tetrahydrofuran, and 2-methyltetrahydrofuran. Examples of the heterocyclic compounds include 3-methyl-2-oxazolidinone and 2-methylpyrrolidone. Examples of the nitrile compounds include acetonitrile, methoxyacetonitrile, and propiononitrile. Examples of the aprotic polar compounds include sulfolane, dimethyl sulfoxide, and dimethyl formamide. These solvents may be used alone or in combination of two or more thereof. Of the above-described solvents, desirable compounds are carbonate compounds such as ethylene carbonate and propylene carbonate, heterocyclic compounds such as y-butyrolactone, 3-methyl-2-oxazolidinone, and 2-methylpyrrolidone, and nitrile compounds such as acetonitrile, methoxyacetonitrile, propiononitrile, 3-methoxypropiononitrile, and valeronitrile.

The solvent may be an ionic liquid alone or a mixture of an ionic liquid and another solvent. Ionic liquids are desirable because of low volatility and high flame retardancy.

Examples of the ionic liquids include imidazolium-based ionic liquids such as 1-ethyl-3-methylimidazolium tetracyanoborate, pyridine-based ionic liquids, alicyclic amine-based ionic liquids, aliphatic amine-based ionic liquids, and azonium amine-based ionic liquids.

### Second Embodiment

A perovskite solar cell 200 according to a second embodiment differs from the perovskite solar cell 100 according to the first embodiment in that the perovskite solar cell 200 further includes a porous layer 7.

Hereinafter, the perovskite solar cell 200 will be described. However, components that have the same functions and configurations as those of components having been described for the perovskite solar cell 100 according to the first embodiment are denoted by the same reference numerals as in the first embodiment and descriptions thereof will be omitted.

Referring to FIG. 2, the solar cell 200 according to the embodiment has a configuration in which, on a substrate 1, a first current-collector electrode 2, an electron transport layer 3, a porous layer 7, a light-absorbing layer 24, a hole transport layer 5, and a second current-collector electrode 6 are stacked in this order. The porous layer 7 is disposed between the electron transport layer 3 and the light-absorbing layer 24. The porous layer 7 contains a porous material.

The substrate 1 may be omitted from the perovskite solar cell 200.

The basic operation and effect of the perovskite solar cell 200 according to the embodiment are as follows.

The operation of the perovskite solar cell 200 is the same as that of the perovskite solar cell 100 according to the first embodiment. The second embodiment provides the same effect as in the first embodiment.

However, in the second embodiment, the porous layer 7 is formed, so that the material for the light-absorbing layer 24 enters pores of the porous layer 7. In other words, the pores of the porous layer 7 are filled with the material for the light-absorbing layer 24. This results in an increase in the surface area of the light-absorbing layer 24, which enables an increase in the amount of light absorbed by the light-absorbing layer 24.

The perovskite solar cell 200 according to the second embodiment can be produced in the same manner as in the perovskite solar cell 100. The porous layer 7 may be formed on the electron transport layer 3 by coating, for example.

Hereinafter, components of the perovskite solar cell 200 will be specifically described.

### Porous Layer 7

The porous layer 7 serves as the scaffold for forming the light-absorbing layer 24. The porous layer 7 does not inhibit light absorption by the light-absorbing layer 24 or movements of electrons from the light-absorbing layer 24 to the electron transport layer 3.

The porous layer 7 contains a porous material. The porous material is, for example, a porous material including a mass of insulating or semiconducting particles. Examples of the insulating particles include aluminum oxide particles and silicon oxide particles. Examples of the semiconductor particles include inorganic semiconductor particles. Examples of the inorganic semiconductor include oxides of metal elements, perovskite oxides containing metal elements, sulfides of metal elements, and metal chalcogenides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, and Cr. More specifically, an example is TiO₂. Examples of the perovskite oxides of metal elements include SrTiO₃ and CaTiO₃. Examples of the sulfides of metal elements include CdS, ZnS, In₂S₃, PbS, Mo₂S, WS₂, Sb₂S₃, Bi₂S₃, ZnCdS₂, and Cu₂S. Examples of the metal chalcogenides include CdSe, In₂Se₃, WSe₂, HgS, PbSe, and CdTe.

The porous layer 7 desirably has a thickness of 0.01 μm or more and 10 μm or less, more desirably 0.1 μm or more and 1 μm or less. The porous layer 7 desirably has high surface roughness. Specifically, a surface-roughness coefficient defined as effective area/projected area is desirably 10 or more, more desirably 100 or more. The projected area is the area of a shadow of an object, the shadow being cast behind the object when light is directed straight toward the front surface of the object. The effective area is the actual surface area of the object. The effective area is calculated from the volume of the object determined by the projected area and thickness of the object, and the specific surface area and bulk density of the material forming the object.

### Light-Absorbing Layer 24

The light-absorbing layer 24 may have the same configuration as that of the light-absorbing layer 4 according to the first embodiment.

### EXAMPLES

Hereinafter, the present disclosure will be specifically described with reference to Examples. Perovskite solar cells of Examples 1 to 3 and Comparative Examples 1 and 2 were produced and evaluated in terms of properties. The evaluation results are summarized in Table 1.

### Example 1

A perovskite solar cell having the same structure as in the perovskite solar cell 200 in FIG. 2 was produced. All the production steps except for production of the second current-collector electrode 6 described below were performed in the air. The perovskite solar cell includes the following components.
Substrate 1: glass substrate, thickness: 0.7 mm
First current-collector electrode 2: fluorine-doped SnO₂ layer (surface resistance: 10 Ω/sq.)
Electron transport layer 3: titanium oxide, 30 nm
Porous layer 7: porous titanium oxide, 200 nm
Light-absorbing layer 24: CH₃NH₃PbI₃, 300 nm
Hole transport layer 5: Spiro-OMeTAD (manufactured by Merck KGaA), 300 nm
Second current-collector electrode 6: gold, 80 nm

The perovskite solar cell of Example 1 was produced in the following manner.

As the substrate 1 and the first current-collector electrode 2, a conductive glass substrate (manufactured by Nippon Sheet Glass Co., Ltd.) having a fluorine-doped SnO₂ layer and having a thickness of 0.7 mm was used.

On the first current-collector electrode 2, a titanium oxide layer having a thickness of about 30 nm was formed by sputtering as the electron transport layer 3.

A high-purity titanium oxide powder having an average primary particle size of 20 nm was dispersed in ethyl cellulose to prepare a titanium oxide paste.

The titanium oxide paste was applied to the electron transport layer 3, dried, and fired at 500° C. for 30 minutes in the air. Thus, a porous titanium oxide layer having a thickness of 0.2 μm was formed as the porous layer 7.

A DMSO (dimethyl sulfoxide) solution was prepared so as to contain 1 mol/L of PbI₂ and 1 mol/L of methylammonium iodide. This solution was applied to the porous layer 7 by spin coating and heat-treated on a hot plate at 130° C. Thus, a CH₃NH₃PbI₃ perovskite layer was formed as the light-absorbing layer 24.

A chlorobenzene solution was prepared so as to contain 60 mmol/L of Spiro-OMeTAD, 30 mmol/L of LiTFSI (lithium bis(trifluorosulfonyl)imide), and 200 mmol/L of tBP (tert-butylpyridine). This solution was applied to the light-absorbing layer 24 by spin coating to form the hole transport layer 5.

Finally, gold was deposited on the hole transport layer 5 so as to form a layer having a thickness of 80 nm. Thus, the second current-collector electrode 6 was formed.

### Example 2

A perovskite solar cell was produced as in the production steps for the perovskite solar cell of Example 1 except for the following points. All the production steps were performed within a glove box. The glove box was prepared so as to have a nitrogen gas (inert gas) atmosphere and a dew point of less than −30° C. The solution for forming the hole transport layer 5 was prepared so as to further contain 0.3 mmol/L of a Co complex (FK209, manufactured by Dyesol Limited). This solution of the same amount as in Example 1 was used to form the hole transport layer 5.

### Example 3

A perovskite solar cell was produced as in the production steps for the perovskite solar cell of Example 1 except for the following point. The solution for forming the hole transport layer 5 was prepared so as to further contain 0.6 mmol/L of the Co complex (FK209). This solution of the same amount as in Example 1 was used to form the hole transport layer 5.

### Comparative Example 1

A perovskite solar cell was produced as in the production steps for the perovskite solar cell of Example 2 except for the following point. The solution for forming the hole transport layer 5 was changed such that the concentration of the Co complex (FK209) was 0.03 mmol/L. This solution of the same amount as in Example 1 was used to form the hole transport layer 5.

### Comparative Example 2

A perovskite solar cell was produced as in the production steps for the perovskite solar cell of Example 2 except for the following point. The solution for forming the hole transport layer 5 was changed such that the concentration of the Co complex (FK209) was 3 mmol/L. This solution of the same amount as in Example 1 was used to form the hole transport layer 5.

### Measurement of Conversion Efficiency

A solar simulator was used to irradiate a perovskite solar cell with light at an illuminance of 100 mW/cm². After the current-voltage characteristic stabilized, the current-voltage characteristic was measured and the conversion efficiency was determined as the initial conversion efficiency. After the initial conversion efficiency was determined, the perovskite solar cell was subjected to a heating test at 85° C. for 1000 hours. After the heating test, the conversion efficiency was determined again on the basis of the measurement of the current-voltage characteristic. The ratio of the conversion efficiency after the heating test to the initial conversion efficiency was calculated as a retention ratio.

### Measurement of Doping Ratio

The doping ratio of the hole transport layer 5 was determined by ultraviolet-visible (UV-Vis) spectrometry. The term “doping ratio” denotes the content ratio of the oxidant moiety in the hole transport layer 5. Specifically, the doping ratio is represented by 100C/(C+D) (%) where C represents the number of moles of the oxidant moiety in the hole transport layer, and D represents the number of moles of the reductant moiety in the hole transport layer.

The reductant moiety of Spiro-OMeTAD serving as the hole transport material has an absorption peak wavelength in the range of 350 to 400 nm. The oxidant moiety of Spiro-OMeTAD has an absorption peak wavelength in the range of 500 to 550 nm. The intensities of these absorption peaks are individually in proportion to the numbers of moles of the reductant moiety and the oxidant moiety. The material of the hole transport layer 5 before the heating test was subjected to UV-Vis spectrometry to measure the peak intensities corresponding to the oxidant moiety and the reductant moiety. On the basis of the measured intensities, the doping ratio was calculated.

TABLE 1

| | Doping | Initial | Conversion | |
|---|---|---|---|---|
| | Ratio | Conversion | Efficiency After | Retention |
| | (%) | Efficiency (%) | Heating Test (%) | Ratio (%) |
| Example 1 | 0.1 | 10.5 | 9.1 | 87 |
| Example 2 | 0.5 | 11.1 | 8.7 | 78 |
| Example 3 | 1.1 | 11.6 | 7.7 | 66 |
| Comparative | 0.05 | 3.1 | 2.1 | 70 |
| Example 1 | | | | |
| Comparative | 5 | 12.6 | 6.7 | 53 |
| Example 2 | | | | |

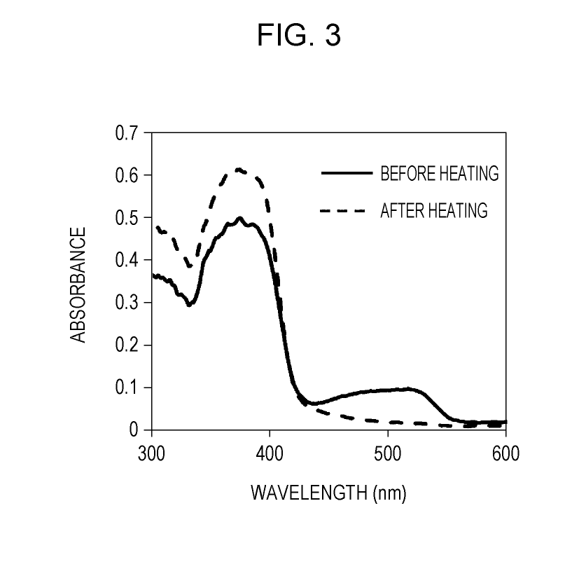

FIG. 3 illustrates the UV-Vis absorption spectra of the hole transport layer 5 of the perovskite solar cell of Example 2. The solid line corresponds to the result before the heating test. The broken line corresponds to the result after the heating test.

The results in FIG. 3 indicate that, in the perovskite solar cell of Example 2 before the heating test, both of the oxidant moiety and the reductant moiety in Spiro-OMeTAD are present. On the other hand, after the heating test, the peak intensity of the oxidant moiety of Spiro-OMeTAD considerably decreases, while the peak intensity of the reductant moiety increases. These results demonstrate that reduction of the oxidant moiety in Spiro-OMeTAD occurred during the heating test.

Comparison between the ratio of the amount of the cobalt complex to the amount of Spiro-OMeTAD in the solution for forming the hole transport layer 5 and the resultant doping ratio in Table 1 has revealed that the doping ratios in Example 1 and Example 3 are unproportionally high. This is because the perovskite solar cells in Example 1 and Example 3 were produced in the air, so that not only the cobalt complex but also oxygen in the air caused oxidation of Spiro-OMeTAD as the hole transport material.

The results in Table 1 also indicate that the perovskite solar cells of Examples 1 to 3 have conversion-efficiency retention ratios of 66% to 87% after the heating test. The actual values of conversion efficiency of these solar cells after the heating test are also as high as 7.7% or more. In contrast, for the perovskite solar cell of Comparative Example 1, the initial conversion efficiency and the conversion efficiency after the heating test are both much lower than those of perovskite solar cells of Examples 1 to 3. For the perovskite solar cell of Comparative Example 2, the initial conversion efficiency is high but the conversion efficiency considerably decreases due to the heating test, so that the retention ratio of the conversion efficiency after the heating test is as low as 53%.

As has been demonstrated above, when C represents a number of moles of the redox moiety in an oxidized state in the hole transport layer and D represents a number of moles of the redox moiety in an reduced state in the hole transport layer, the hole transport layer satisfies Formula (1). Accordingly, a decrease in the conversion efficiency of the perovskite solar cell during use for long hours can be suppressed. As a result, the perovskite solar cell has enhanced durability.

A perovskite solar cell according to the present disclosure is useful as a photoelectric conversion element or an optical sensor.

What is claimed is:

1. A perovskite solar cell comprising:
a first electrode;
an electron transport layer on the first electrode, containing a semiconductor;
a light-absorbing layer on the electron transport layer, containing a perovskite compound represented by a compositional formula ABX₃ where A represents a monovalent cation, B represents a divalent cation, and X represents a halogen anion;
a hole transport layer on the light-absorbing layer, containing a hole transport material including a redox moiety, and
a second electrode on the hole transport layer, wherein
the hole transport layer satisfies
0.1≦100C/(C+D)≦1.1 (1)
where C represents a number of moles of the redox moiety in an oxidized state in the hole transport layer, and D represents a number of moles of the redox moiety in a reduced state in the hole transport layer.

2. The perovskite solar cell according to claim 1, wherein the monovalent cation includes at least one cation selected from the group consisting of a methylammonium cation and a formamidinium cation.

3. The perovskite solar cell according to claim 1, wherein the divalent cation includes at least one cation selected from the group consisting of Pb²⁺, Ge²⁺, and Sn²⁺.

4. The perovskite solar cell according to claim 1, wherein the hole transport material includes an aromatic amine derivative represented by Chemical Formula below 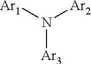
where Ar₁, Ar₂, and Ar₃ each independently represent one of a substituted aryl group, unsubstituted aryl group, a substituted heteroaryl group, a unsubstituted heteroaryl group, a substituted heterocyclic group, and a substituted heterocyclic group.

5. The perovskite solar cell according to claim 4, wherein at least two of Ar₁, Ar₂, and Ar₃ are linked together to form a ring structure.

6. The perovskite solar cell according to claim 1, further comprising a porous layer between the electron transport layer and the light-absorbing layer, containing a porous material.

7. The perovskite solar cell according to claim 1, wherein the hole transport layer contains a cobalt complex.
